(19) United States
(12) Patent Application Publication
(10) Pub. No.: US 2024/0035298 A1
(43) Pub. Date: Feb. 1, 2024

(54) PLATFORM FOR SPACE-SAVING CONFIGURATION OF AN ENERGY CONVERSION INSTALLATION, AND ENERGY CONVERSION INSTALLATION

(71) Applicant: SMA Solar Technology AG, Niestetal (DE)

(72) Inventor: Andreas Falk, Kassel (DE)

(21) Appl. No.: 18/485,341

(22) Filed: Oct. 12, 2023

Related U.S. Application Data
(63) Continuation of application No. PCT/EP2022/054222, filed on Feb. 21, 2022.

(30) Foreign Application Priority Data
Apr. 15, 2021 (DE) 10 2021 109 550.6

(51) Int. Cl. E04H 5/04; H05K 9/00

(52) U.S. Cl. CPC E04H 5/04; H05K 9/0081

(57) ABSTRACT

The disclosure relates to a platform stack for the space-saving configuration of an energy conversion installation, comprising at least two platforms stacked one over another to form the platform stack, wherein each of the platform is configured to position a skid with a respective converter unit of the energy conversion installation such that they are stacked one on top of the other on via the two platforms. The platforms each include a frame structure having a storage surface for the skid, and have alignment elements on a first side and support posts on a second side of the frame structure, opposite the first side.

### REFERENCE TO RELATED APPLICATIONS

This Application is a Continuation of International Application number PCT/EP2022/054222, filed on Feb. 21, 2022, which claims the benefit of German Application number 10 2021 109 550.6, filed on Apr. 15, 2021. The contents of the above-referenced Patent Applications are hereby incorporated by reference in their entirety.

### FIELD

The disclosure relates to a platform for a space-saving configuration of an energy conversion installation. Furthermore, the disclosure relates to an energy conversion installation having such a platform.

### BACKGROUND

Energy generation from renewable energy sources, in particular from solar cells, is becoming increasingly important, and the proportion of the electrical power obtained in this way in power grids rises constantly. For this purpose, for example, energy conversion installations are used which can have converter units as components. Such converter units have components which can be, for example, inverters or energy storage devices, such as batteries. Inverters with a converting power in the range of several megawatts are in use today. They can be integrated in housings with standardized dimensions and/or standardized grab points of a cargo container—in particular, a standardized air or sea cargo container. Accordingly designed container-like housings allow transport with established transport and loading logistics, and provide the power electronics with sufficient protection against weather, both during transport and during operation. Inverters in the container housing are regularly installed on the ground on suitably designed foundations so that they are easily accessible for installation and for maintenance purposes.

If it is then necessary to install an energy conversion installation which is arranged in direct spatial proximity to a consumer with a very high consumption capacity, and which stabilizes the grid connected to the consumer, the arrangement in containers reaches its limits—inter alia because the containers would possibly be too close to one another to enable access to the individual containers for installation or maintenance purposes, and/or because a sufficient cooling of the electronic components in the containers is no longer possible. This is the case in particular when a converter unit in the container itself is sufficiently protected against environmental influences and therefore additional protection against environmental influences by the container is not absolutely necessary. In this case, the additional protection of the converter unit from environmental influences by the container would tend to be disadvantageous, since it usually worsens the heat dissipation of the converter unit, due to the additional housing of the container. A further example of this can be an energy conversion installation which serves as a system for grid support with the aid of a provision of reactive and/or active power for a subgrid in an urban area.

The document CN 110486152 A discloses a stacked generator set which has multiple containers stacked vertically. A generator is arranged in each of the containers. Multiple heat dissipation devices are arranged above the uppermost container.

Document EP 2101017A2 discloses a portable data center with one or more modular containers that form a modular enclosure structure. The data center can thus quickly be set up at a remote location and put into operation in a simple manner.

### SUMMARY

The disclosure is directed to a platform which enables a space-saving and/or easily accessible arrangement of converter units of an energy conversion installation, for example, when these converter units are protected from environmental influences by themselves in such a way that they do not require any additional protection against environmental influences, for example, in the form of an additional housing by a container. The best possible heat dissipation must be ensured for the converter units in operation. The disclosure is also directed to a space-saving energy conversion installation having such converter units.

A platform suitable for the space-saving configuration of an energy conversion installation is configured for positioning a skid with a converter unit of the energy conversion installation on the platform and configured for stacking it one over another with a further platform with a further skid positioned thereon and a further converter unit of the energy conversion installation, in the form of a stack. A skid is to be understood as a flat, for example palleted, supporting framework on which various components of the converter unit, for example, DC/DC converter, switchgear assembly, DC/AC converter, transformer, can be preassembled. The platform can be stacked one over another with one further or several further platforms. The expression “one further platform” is therefore to be understood to mean at least one further platform.

In one embodiment, the platform comprises a frame structure with a support surface for the skid. In this case, the platform is at least largely free without a wall surrounding the support surface around its periphery. The platform has alignment elements on a first side of its frame structure, and support posts on a second side of the frame structure opposite the first side. In the stacked state, the first side can be regarded as the underside of the platform; and the second side can be regarded as the upper side of the platform in the stacked state. Alternatively, however, it is also possible for the first side to be considered as the upper side of the platform and the second side to be regarded as the underside of the platform in the stacked state. The support surface for the skid is arranged in one embodiment on the upper side of the platform. In addition, the frame structure forms a standing surface which extends at least predominantly along the circumference of the support surface and can be walked on by persons, and can be used as access to the converter unit. In one embodiment, the standing surface is formed circumferentially along the entire circumference of the support surface, and thus provides accessibility from both directions of the circumference.

The support posts of the platform are configured in such a way that their ends interact with the alignment elements of the further platform in a stacked state such that they lead to a laterally centered and vertically spaced arrangement of the support surface of the platform and the support surface of the further platform within the stack. This is in particular the case when the further platform is arranged in the stack above the platform. The support posts of a platform are configured in one embodiment identically to one another. In one embodiment, the support posts of the platform and the support posts of the further platform are configured identically to one another. Alternatively or additionally, the alignment elements of the platform are designed and arranged such that they interact in a stacked state with ends of the support posts of the at least one further platform, in such a way that they lead to a laterally centered and vertically spaced arrangement of the support surface of the platform and the support surface of the further platform within the stack. This is in particular the case when the further platform is arranged in the stack below the platform. The alignment elements of a platform are configured in one embodiment identically to one another. In one embodiment, the alignment elements of the platform and the alignment elements of the further platform are configured identically to one another. The interaction can, for example, be configured such that a projection of the alignment element engages in a recess of the support post, or vice versa.

In one embodiment, a free space for receiving the converter unit arranged on the skid or the further converter unit arranged on the further skid is formed within the stack between the support surfaces of the platform and the further platform. Since the platform itself is at least largely without a wall surrounding its support surface, the free space formed within the stack for receiving the skid and the converter unit is at least largely without a wall surrounding the free space circumferentially. As a result, a sufficient distance between the converter units, and thus at the same time sufficient ventilation, can be ensured.

As a result, the platform serves as a component of a modular system for stacking converter units, which allows sufficient accessibility also of converter units which are arranged one above the other, and which at the same time enables sufficient cooling of the converter units. The platform makes it possible to stack skids with converter units which are arranged or can be arranged thereon in each case. For this purpose, the skid can be arranged with the converter unit on a platform. Multiple platforms each with the combination of skid and converter unit are then stacked one above the other. For this purpose, the platforms have support posts on which a platform lying above can come to rest. In this way, a stack of platforms with converter units arranged thereon can be created, which makes it possible to arrange the converter units in a space-saving and easily accessible manner, and at the same time ensure sufficient ventilation.

In one embodiment, optimal cooling of the converter units in operation is made possible according to the disclosure in that the platform is at least largely without a wall surrounding the support surface along its circumference, and thus also without an additional housing for the converter unit—as would occur, for example, if the converter unit were housed in a container. Specifically, it is significantly more difficult to implement the heat dissipation of a converter unit enclosed in a container, due to the accumulation of dust forming there. In contrast, the platform according to the disclosure, as well as a stack of multiple platforms according to the disclosure, has a largely open structure in one embodiment, as a result of which a significantly better thermal coupling of the converter units to their cooling environment is achieved. The thermal coupling to the environment is at least significantly better than is the case with a container-like enclosure of the converter units. This results in better heat dissipation of the converter units stacked one above the other by means of the platforms according to the disclosure relative to those which are stacked on top of one another in containers. This is advantageous in particular if the converter unit itself is protected against environmental influences due to its own housing or the housing of its components, and therefore additional protection against environmental influences is not necessary by an additional container-like enclosure. The feature that the free space formed within the stack for receiving the skid and the converter unit is “at least largely” without a wall surrounding the free space can be interpreted according to the disclosure in such a way that a wall possibly present on the peripheral surface of the free space assumes at most 49% of the peripheral surface on the sides surrounding the free space. The feature that “the platform is at least largely without a wall surrounding the support surface on the circumference” can be interpreted in a corresponding manner—namely, in such a way that ultimately the corresponding feature is fulfilled with respect to the free space within the stack.

In one embodiment, the support surface for the skid has a fire retardant material. In particular, the platform can have a sandwich construction of two metal sheets and an intermediate non-combustible insulating material for this purpose. This can lead to improved fire protection within the stack. In addition, the support posts and/or other parts of the platform can also be clad in a fire-retardant manner.

In one embodiment of the platform, one or more sprinkler heads for firefighting can be attached to the frame structure. In this case, the sprinkler head or the sprinkler heads is/are oriented in such a way that a component of the converter unit arranged on the platform and/or a component arranged underneath the platform in the stack is exposed to the discharged liquid. This can lead to improved fire protection within the stack.

In one embodiment of the platform, the alignment elements are configured in such a way that they do not only allow stacking of the platform on a further platform, but also a stacking of the platform on a container. Specifically, the alignment elements can surround upper corners of a container when the platform is stacked on the container, thereby enabling lateral centering and fixing of the platform on the container. This enables a flexible arrangement of the platform in a stack, making possible both an arrangement on a container and an arrangement on a further platform, and in particular without modification to the platform, or at most with a low-effort modification of the platform.

The frame structure thus forms a standing surface in one embodiment which is arranged outside the support surface and can be walked on by persons as access to components which can be arranged or are arranged on the support surface. As a result, for example, maintenance personnel can also easily carry out installation and maintenance work on the components, e.g., on the converter unit, when they are located further above in the stack. In order to provide sufficient freedom of movement for the personnel for carrying out this work, the standing surface should, for example, have a width of at least 1 m, preferably at least 1.5 m. Advantageously, the standing surface also has sufficient load-bearing capacity for mechanical loads which are produced by spare parts or tools placed thereon for carrying out the installation and maintenance work.

In one embodiment of the platform, the standing surface is formed by placing floor panels in the form of gratings. Since gratings are air permeable, ventilation in the area between platforms is not affected. Furthermore, rain water does not collect on the standing surface, so that no separate measures are required for drainage.

In one embodiment, the platform has retaining elements in the region of the support surface for feeding supply lines to the skid and/or the converter unit arranged thereon. The retaining elements can be configured, for example, as clamps or brackets, and serve to place the ends of the supply lines at specified positions of the platform before a skid and/or a converter unit arranged thereon or to be arranged thereon is placed in the region of the support surface. These positions then correspond to the regions in which the connections for the supply lines are arranged on the skid and/or a converter unit arranged thereon or to be arranged thereon, so that a simple connection of the supply lines is made possible. The supply lines can comprise, for example, electrical lines, gas lines or supply lines of operating media of the energy conversion installation. For example, the supply lines can be configured to transport a liquid for sprinkler components of the energy conversion installation for accidents.

In one embodiment, fastening elements, e.g., sleeves, for a railing laterally delimiting the standing surface, can be provided on the platform to protect personnel using the standing surfaces from falling. Such a railing can then be easily attached as needed, or permanently.

In one embodiment, a height of the platform is between 350 cm and 400 cm. This allows an appropriate arrangement of converter units of e.g., an energy conversion installation. Taking into account a typical height of converter units, it is thus ensured that the load to be supported is born by the support posts. The converter unit can thus be relieved of the load. The height of the platform corresponds—as also shown in FIG. 1, for example, as the dimension “H”—to a distance between an underside of the frame structure and an upper end of the support posts, and is thereby determined substantially by the height of the support posts. Furthermore, with the height of the platform defined in this way, it is ensured that a further free space is formed in the stack between converter units stacked one above the other, which thus supports sufficient cooling of the converter units in their operation.

In one embodiment of the platform, the alignment elements or the ends of the support posts particularly each have a twist-lock fastening. A variant of a twist-lock fastening is known, for example, from the Conpar Limited company. In this case, the platform in one embodiment has alignment elements which also enable the locking, in addition to the orientation, of two platforms to each other. For this purpose, for example, a recess can be provided on both platforms as part of the alignment element. It is also possible for a twist-lock fastening to be fixedly attached to an underside of a platform as a component of the alignment elements, wherein only the lower platform, for example, has, in the region of the ends of the support elements, a recess into which the twist-lock fastening can engage for locking. Alternatively, it is possible for twist-lock fasteners to be mounted in a comparable manner not on the underside of the platform but on the support posts of the platform—in particular fixedly attached. In this way, they can form part of the support posts, in particular as a part of the ends of the support posts.

An energy conversion installation for exchanging electrical power with a grid has a stack formed from at least two platforms, wherein a skid with a converter unit arranged thereon is positioned on each of the platforms. An electrical connection, and/or a media connection, can be guided to the upper platform via the platform, and access to the upper platform for performing work, e.g., on converter units arranged thereon, is possible.

In one embodiment, the energy conversion installation has a sprinkler system with multiple sprinkler heads and supply lines connected thereto for supplying liquid, wherein the supply lines and/or the sprinkler heads have an electric heater. The liquid can be, for example, water or another extinguishing medium, wherein the electric heating is provided in order to prevent the water or extinguishing medium from freezing at low outside temperatures and to prevent damage caused by this to the supply lines and/or the sprinkler heads.

In one embodiment of the energy conversion installation, the converter units arranged on the skids each have one or more DC/AC converters, one or more DC/DC converters, one or more transformers and/or one or more switching systems. In addition, the converter unit can also include a central control unit, which can optionally be supplied with power via a buffer energy supply, for example, in the form of a battery. Although it is possible here for the converter units to have the same design, it is not absolutely necessary. Rather, it is possible for the converter units to be designed differently from one another and, in particular, to include different components, both in terms of their type and their number.

In one embodiment of the energy conversion installation, the stack additionally comprises at least one container as a housing for components of the energy conversion installation. Advantageously, the platform and the further platform are stacked on the at least one container.

The energy conversion installation can be configured to provide reactive power in the grid and/or to stabilize the frequency of the grid. Alternatively or additionally, the energy conversion installation is designed as an uninterruptible power supply system which has decoupling elements to the grid and an energy storage device.

In one embodiment, the energy conversion installation additionally has an electrolyzer which is arranged in a container or on one of the platforms. Of course, it is also possible for the energy conversion installation to comprise multiple electrolyzers. In this case, electrical power of the connected grid can be used for the production of hydrogen. As a result of the arrangement of the platforms as a stack, such an energy conversion installation can easily be scaled as required in its operating power with little space requirement.

In one embodiment of the energy conversion installation, the stack has two containers which are stacked one above the other with the interposition of a container platform, wherein the two platforms are arranged on the upper of the two containers.

In one embodiment, the energy conversion installation has a plurality of stacks which are arranged next to one another in such a way that the platforms of adjacent stacks adjoin one another, so that a common plane of standing surfaces is formed. Any gaps formed between the platforms may be covered by metal sheets, for example. It is also conceivable to increase the stability of the stack arrangement by means of a, in particular elastic, connection—for example a screw connection—or the use of buffer elements, between the platforms of adjacent stacks.

Adjacent stacks can also extend in particular in two different lateral directions, so that a cluster of platforms is formed. In this case, the stacks can be enclosed by a facade for forming a building structure. In an outer region of the stack clusters, a shared access to the platform planes can be realized by a staircase or an elevator. In this case, a height and/or a material of the facade can be selected such that the noise level for adjacent residential buildings is kept below a permitted noise level. This makes use of the fact that noise propagates significantly only along an imaginary line originating from the noise source, but does not penetrate the façade. The height of the façade can thus be selected such that the noise reaching the upper floors of adjacent residential buildings, due to a noise source arranged far above in the stack, for example the converter unit arranged there, is not at a nuisance level. Nuisance noise still passing through the façade can be reduced via the material of the façade. For example, the façade can contain sound-absorbing or sound-reflecting material, as is also used in noise protection walls on traffic roads. The allowed noise level can differ regionally and can be taken from relevant guidelines for noise protection.

It is possible for a gap to remain between a lower edge of the facade and the ground at least in regions, through which gap an air exchange with the surroundings is possible, so that cooling air can flow out of the environment at any time in sufficient quantity. It is also possible for the energy conversion installation to have a raised base with which the facade overlaps, in such a way that a gap is formed between the facade and the base, which gap allows air exchange. The raised base can be part of a concrete building with one or more floors in which, for example, rechargeable batteries or other storage elements are arranged.

In one embodiment of the energy conversion installation, the upper of the platforms of one or more of its stacks can have a metallic cover that covers the top of the converter unit arranged there. The metallic cover may be electrically connected to ground. In this case, the metallic covers of adjacent stacks of the energy conversion installation can be connected to one another in such a way that a continuously conductive surface is produced. By means of the metallic cover, an emission of electromagnetic interference radiation of the converter unit or converter units arranged under the cover into the environment can be reduced. An irradiation of electromagnetic interference radiation from the surroundings to components of the energy conversion installation can also be reduced as a result. Alternatively or cumulatively, the cover can also be used as a lightning protection for the components of the energy conversion installation arranged under the cover.

Since the cover does not carry heavy loads, it does not have to be designed to be extremely stable mechanically. In one embodiment the metallic cover can be configured to be largely air-permeable, so that heated air can escape upward through the metallic cover. For example, the cover can comprise a metal grating, or in particular a metal grating. A mesh width of the metal grating can be matched to a frequency of the electromagnetic interference radiation to be shielded. In the frequency range of interest here, the mesh width can lie in particular between 20 mm and 200 mm.

By means of the metallic cover, emission of electromagnetic interference radiation at the top is substantially shielded. Electromagnetic interference radiation exiting laterally from the energy conversion installation can also be shielded by a corresponding embodiment of the facade. For this purpose, the facade can have, for example, a metallic lamination or also a metal grating, which are advantageously each connected to ground.

In one embodiment of the energy conversion installation, the converter unit is designed to be protected from sprayed water from water jets. The converter unit is thus protected from weather influences, and also when the sprinkler system is used, and the power electronics of the converter unit cannot be damaged in the case of adverse weather conditions and/or an activated sprinkler system. In this way, the converter unit itself is suitable for outside use without an additional housing, for example in the form of an additional container.

### BRIEF DESCRIPTION OF THE FIGURES

The disclosure is illustrated below with reference to the drawings, in which:

FIG. 1 shows an embodiment of a platform according to the disclosure in several views,

FIG. 2A shows a perspective view of an embodiment of the platform according to the disclosure, comprising a skid and a converter unit arranged thereon,

FIG. 2B shows a perspective view of a stack with multiple platforms,

FIG. 3A shows a perspective view of a container having a platform, skid and converter unit,

FIG. 3B shows a side view of a container with a platform arranged thereon;

FIG. 3C shows a perspective view of a stack with two platforms,

FIG. 3D shows an energy conversion installation with stacks of platforms arranged next to each other on containers,

FIG. 4A shows a schematic illustration of a twist-lock,

FIG. 4B shows a schematic illustration of a screw connection,

FIG. 5 shows a schematic illustration of a converter unit on a skid,

FIG. 6A shows an embodiment of a container platform with several views,

FIG. 6B shows a perspective view of two containers with a container platform arranged therebetween,

FIG. 7 shows an energy conversion installation designed as a building structure with stacks arranged next to one another,

FIG. 8 shows an embodiment of a platform with a metallic cover.

### DETAILED DESCRIPTION

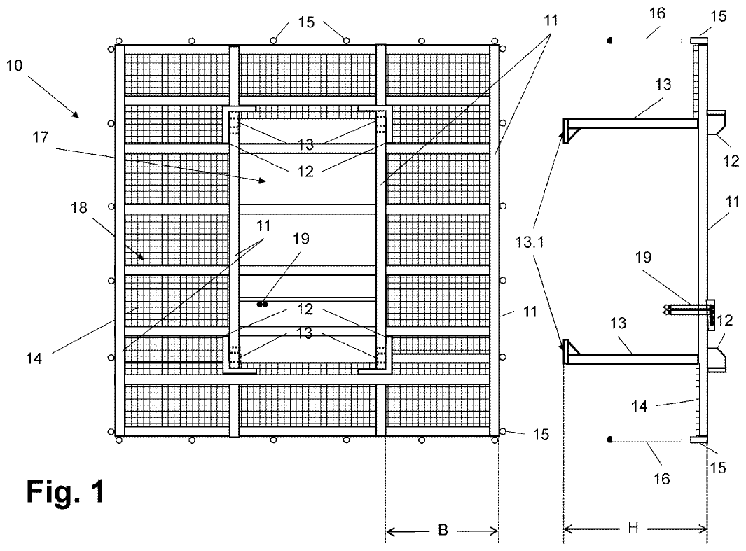

FIG. 1 shows an embodiment of a platform 10 according to the disclosure, which has a frame structure made of a plurality of beams 11 fixedly connected to one another, which defines a support surface 17. The platform 10 is shown in a plan view and a side view to the right thereof. The support surface 17 is arranged in an inner region of the platform and has alignment elements 12 and support posts 13 in the region of its corner points. In one embodiment, the alignment elements 12 and the support posts 13 are arranged on opposite sides of the platform 10. The alignment elements 12 are configured to interact with ends 13.1 of the support posts (of a further platform 10) in order to align and, for example, also lock together the two platforms in one embodiment. For this purpose, the alignment elements 12 can be configured, for example, as so-called corner casting or twist-lock fastenings. It is also possible in one embodiment for the alignment elements 12 to have corner castings in combination with twist-lock fasteners.

The height H of the platform is substantially determined by the length of the support posts 13 plus the thickness of the beams 11. Floor panels 14 are placed on the frame structure in an outer region of the platform surrounding the inner region, such that the outer region can be walked on within a width B, and forms a standing surface 18, so that, in particular, loads can also be positioned there. The floor panels 14 may comprise air- and/or liquid-permeable gratings. It is also conceivable in one embodiment for the frame structure to have a standing surface 18 in the form of an outer region, which can be walked on and which can bear loads, for example, on three sides of the inner region.

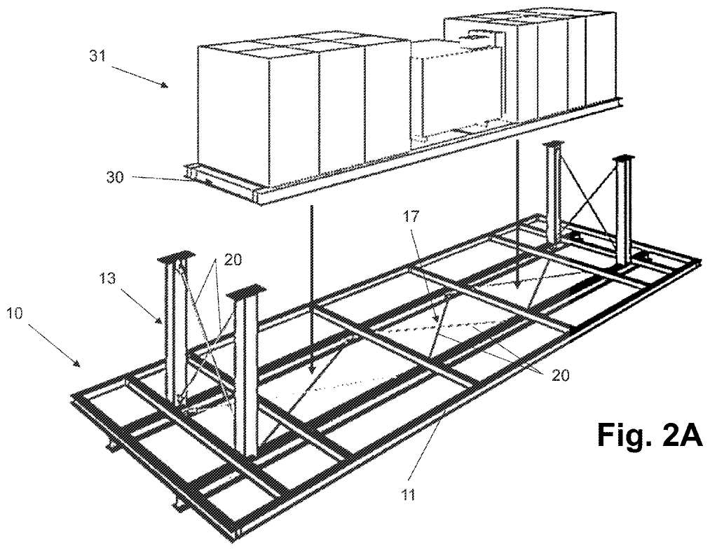

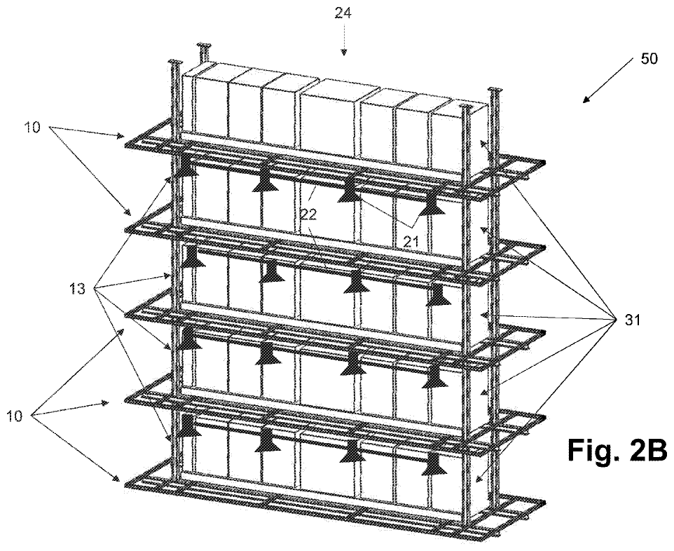

Furthermore, the platform has guide elements, for example, cable channels, by means of which the supply lines are guided. In the inner region, retaining elements 19 are arranged, for example, on a cross-member of the frame structure in order to fix the supply lines at a specified position of the platform 10, in the vicinity of which a connection region is located. In this way, a simple connection of a platform 10 and/or a converter unit 31 (see FIG. 2A) located on the platform can be accomplished via the supply lines. The connection can be an electrical connection, for example, to an AC voltage grid or to a DC voltage bus. Alternatively or cumulatively, however, it is also conceivable for the supply lines to be configured to supply or discharge media for operation of the energy conversion installation, for example, coolant or gases.

Furthermore, fastening elements for a railing 16, in the form of sleeves 15 are attached along the outer beams 11, into which fastening elements the uprights of the railing 16 can be inserted. These fastening elements can be arranged circumferentially on all sides of the platform 10, only on some sides, or on no side.

The arrangement of a skid 30 with a converter unit 31 on the support surface 17 of the platform 10 is shown in perspective in FIG. 2A. The skid 30 with the converter unit 31 can be positioned in the direction of the arrow on the support surface 17, e.g., within the support posts 13. In this case, the skid 30 with the converter unit 31 can also be longer or wider, for example, than the distance between two pairs of support posts 13—and therefore projects, for example, in the longitudinal direction or transverse direction between two support posts 13. In one embodiment, cross-braces 20 can stabilize platform 10. The cross-braces 20 can be arranged, for example, in the inner region of the platform 10 and/or between support posts 13.

FIG. 2B is a perspective view of a stack 24 of five platforms 10 arranged one above the other in the stack 24. The support posts 13 of each platform 10 interact with the alignment elements 12 of the platform arranged above them in order to align the platforms 10 relative to each other and optionally lock them together. A distance, in particular a free space, is formed in the stack 24 via the support posts 13, for example, a free space between the support surfaces 17 of two platforms 10 stacked one above the other—in which then, for example, a converter unit 31, e.g., of an energy conversion installation 50, can be arranged. Sprinkler heads 21 with supply lines 22 can likewise be arranged on the platforms 10 in order, for example in the event of a fire, to allow cooling of the converter units 31, and an extinguishing of a fire, by sprinkling or spraying with a liquid if necessary.

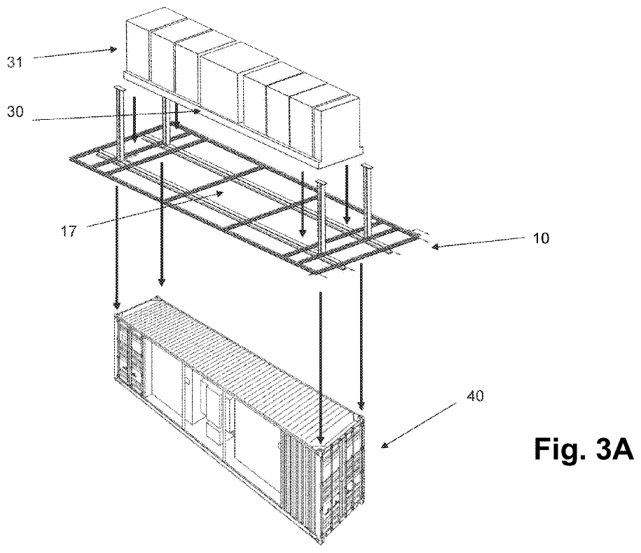

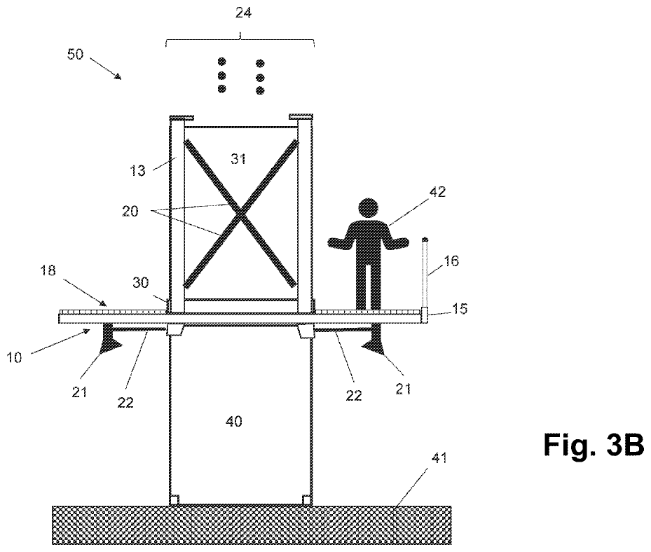

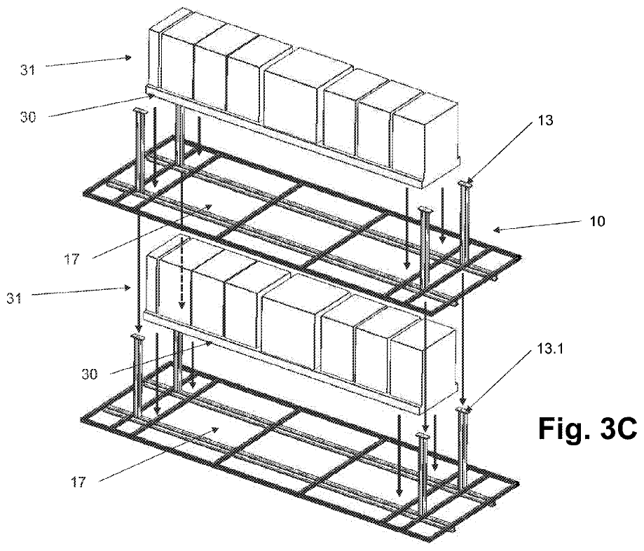

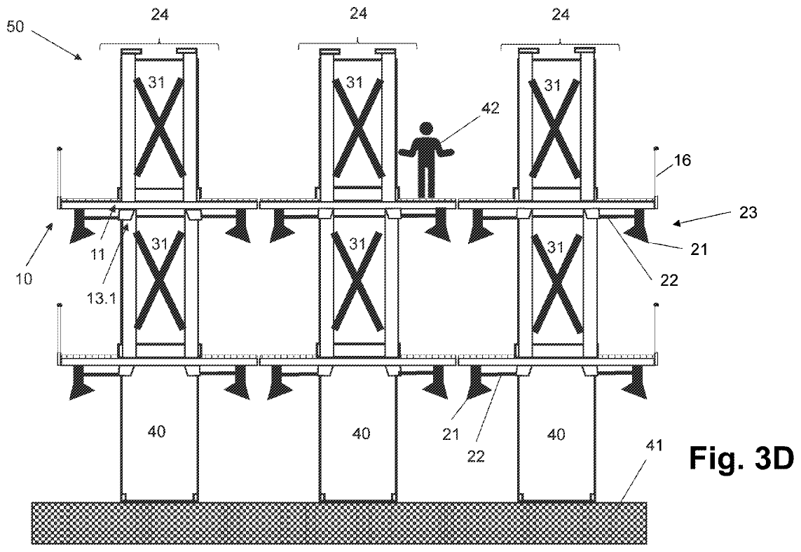

FIG. 3A shows a perspective view of how the platform 10 can be arranged on a container 40 by means of its alignment elements 12 in the direction of the arrow. The platform 10 with skid 30 and converter unit 31 is placed on the container 40 in such a way that alignment elements 12 of the platform 10 are placed on the standardized receiving points of the container which are positioned at the corners of the container, and thus the platform assumes a defined position relative to container 40. The platform 10 and the container 40 can also be locked via the alignment elements 12. For example, it is possible in this case for the alignment elements 12 to be configured in each case as twist-lock fasteners (not shown in FIG. 3A) or to each have a twist-lock fastener.

FIG. 3B shows an energy conversion installation 50 which has multiple converter units 31 in a stack 24 according to one embodiment. In FIG. 3B, only one converter unit 31 is explicitly shown. However, further converter units 31 are arranged above the explicitly illustrated converter unit 31, which is symbolized in FIG. 3B by the points above the converter unit 31. A container 40 is arranged under the illustrated converter unit 31, which container can serve, for example, as a component housing for further components of the energy conversion installation 50. The converter unit 31 and/or the components of the energy conversion installation 50 can comprise power electronic circuits, for example, DC-to-AC converters and/or have a DC/AC converter as a component. In addition, it is possible for the components of the energy conversion installation 50 also to comprise an energy storage device, for example in the form of rechargeable batteries. An electrical load such as an electrolysis unit can also be contained as a component in the container 40, and/or be part of the converter unit 31. The container 40 is placed on a foundation 41. Connecting elements for electrically connecting the power electronic circuit or the energy storage device can be integrated in the foundation 41. A platform 10 is placed on an upper side of the container 40 such that the alignment elements 12 of the platform 10 are placed on the standardized receiving points of the container which are located at the corners of the container 40. In this way, the platform 10 can assume a defined position, both with respect to the container and with respect to the further platforms 10. As a result of the aligned arrangement, it is possible to place a further platform 10 on the platform 10 and thus to form a stack 24 with a plurality of platforms 10. Depending on the weight load capacity of the container 40 and/or the platforms 10, and in compliance with the stability requirement relative to a lateral force—for example, exerted by sidewind—stacks 24 of, for example, one container 40 and four or more platforms 10 can be formed. In each case, a sprinkler 21 with supply lines 22 can be attached to the platforms. In this case, the platforms 10 can be locked to each adjacent container 40 in the stack 24, and/or each adjacent platform 10, which enhances the stability of the stack 24.

The outer region 18 of the platform 10, as a standing surface which can be walked on and can bear a load, enables a person 42 to access elements arranged on the platform 10, for example, the converter unit 31. The person 42 thus has access to the converter unit 31 and, for example, can perform installation or maintenance work at a height above the foundation 41 for which a mobile working platform would otherwise be required. Access to the standing surface 18 can take place via a staircase or a ladder.

An effective cooling of all the converter units 31 and the container 40 can be ensured by the length of the support posts 13 being adequate therefor, as well as by the air-permeable floor panels 14, since a substantially unimpeded air exchange can take place. Also, discharge of water from precipitation need only take place in the plane of the foundation 41.

FIG. 3C shows, by way of example, a perspective view of how the platform 10 can be arranged on the support post 13 of a further platform by means of its alignment elements 12 in the direction of the arrow. Specifically, the platform 10 with the skid 30 and the converter unit 31 is placed on the further platform 10 with the skid 30 and the converter unit 31 in such a way that the alignment elements 12 of the platform 10 interact with the ends 13.1 of the support posts 13 such that the platform 10 assumes a defined position relative to the further platform 10. The interaction of the alignment elements 12 and the ends 13.1 of the support posts can, for example, take place in such a way that a part of the alignment elements 12 engages in e.g., a recess 13.1 of the support post 13.

The frame structure 11 of the upper platform 10 is placed with the alignment elements 12 on the ends 13.1 of the support posts 13 of the lower platform such that the upper platform 10 comes into a position aligned with the lower platform 10. By inserting floor panels 14 into the frame structure 11 of the platform 10, a walkable standing surface 18 is formed, which can extend, for example, completely around the platform 10 and thus enable access to the upper converter unit 31 on all sides.

As shown in FIG. 3D, a plurality of stacks 24 of containers 40 and platforms 10 can be placed next to each other and/or one behind the other on a foundation 41 and thus form a common energy conversion installation 50, wherein the stacks 24 are then lined up in one or two horizontal directions. The platforms 10 of the stacks 24 arranged next to each other and/or one behind the other then form a continuous plane of standing surfaces 18, with a gap remaining between the adjacent platforms 10—which gap can be covered, for example, with metal sheets, if necessary. A railing 16 is then only required on the outer sides of the stacks 24. Access, for example a stair access, to the levels of the standing surfaces 18 can likewise be arranged on the outer side.

In the arrangement shown in FIG. 3D, it is furthermore possible to exchange any platform 10 and/or any container 40 with little effort, in that the platform 10 or the container 40 is lifted vertically out of the arrangement after the electrical and/or further connections are disconnected, by means of a crane, after the platforms 10 which are possibly located above have likewise been lifted vertically. The platforms 10 lying above are temporarily set down, the given platform 10 and/or the given container 40 are exchanged, and the platforms 10 are each stacked up again as stacks 24 within the arrangement. The electrical and/or further supply lines are then connected to one another again.

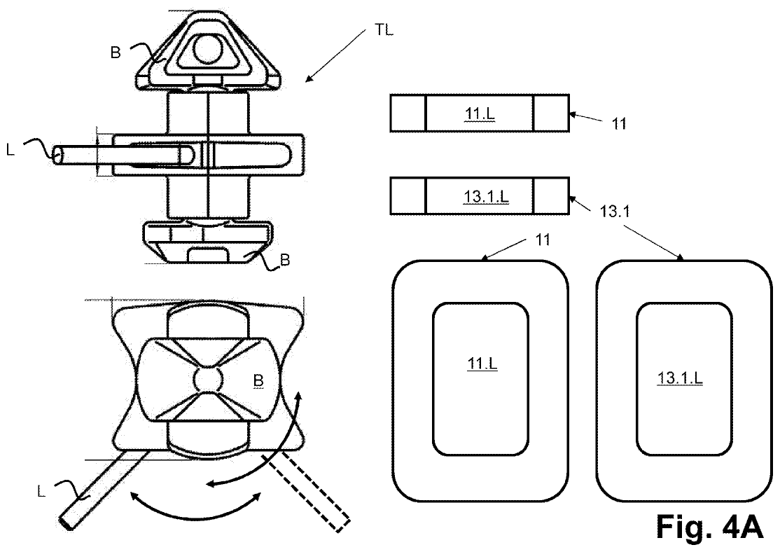

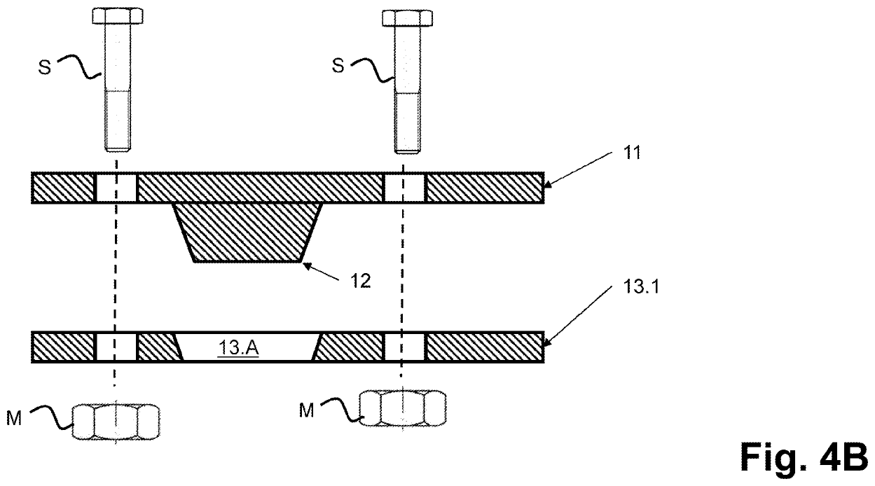

FIG. 4A shows by way of example a twist-lock fastener TL. Such a twist-lock fastener TL can be a component of an alignment element 12, for example. Alternatively, but functionally equivalent, it is possible that the twist-lock fastener TL is not part of the alignment element 12 when the platforms are stacked one above the other, but rather a component of the support post 13, for example, its end 13.1. Bolts B of the twist-lock fastener TL can be moved via a lever L. If the twist-lock fastener TL is arranged such that a bolt B is located in a longitudinal recess 11.L of a beam 11 of an upper platform and its second bolt B is in a longitudinal recess 13.1.L of an end 13.1 of a support post 13 of a lower platform 10, the position of the two platforms 10 can be aligned by rotating the lever L, and the two platforms 10 can be locked against each other.

FIG. 4B shows by way of example a screw connection with a screw S and a nut M, by means of which a beam 11 of a platform 10 (above in the stack 24) can be screwed to an end 13.1 of a support post 13 of a platform 10 (below within the stack 24). In this case, the alignment element 12 is configured as a downwardly projecting conical tapering shaped element. In contrast, the end of the support post 13.1 opposite the alignment element 12 has a recess 13.A accommodating the molded element. In one embodiment, the recess 13.A, in accordance with the alignment element 12, can also have a downwardly oriented conical tapering. When the platforms are stacked one above the other, the alignment element 12 of the upper platform 10 then engages in the corresponding recess 13.A of the end 13.1 of the support post 13 of the lower platform 10, by means of which a lateral centering of the upper platform 10 to the lower platform 10 is generated. FIG. 4B shows by way of example the alignment element 12 of the upper platform in the form of a downwardly extending, conically tapered shaped element, whereas the end 13.1 of the support post 13 of the lower platform 10 has a corresponding recess 13.A. Alternatively, however, it is also possible for the alignment element 12 of the upper platform 10 to have the recess, while the end 13.1 of the support post 13 of the lower platform has a molded element which is conically tapered upward in this case.

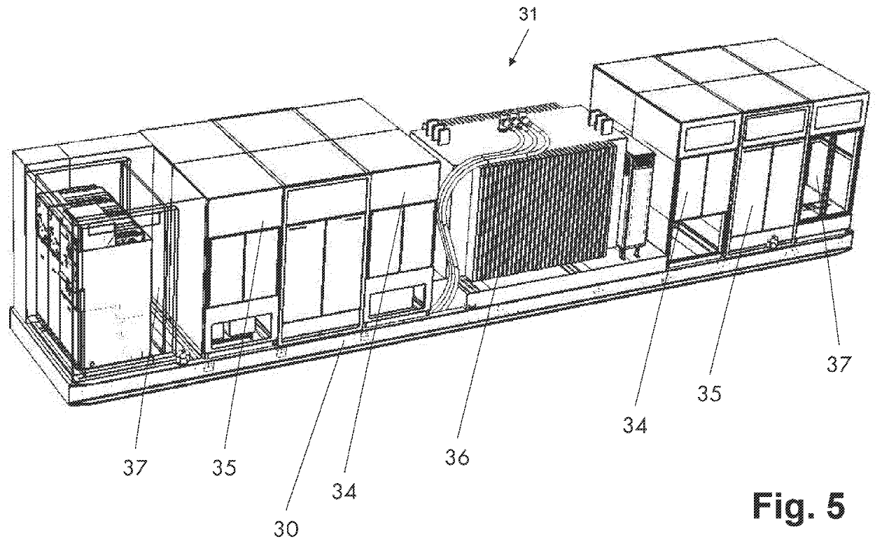

FIG. 5 shows, by way of example, components of a converter unit 31 arranged on a skid 30. The converter unit 31 has two switching systems 37, two DC/DC converters 35, two DC/AC converters 34 and a transformer 36. However, the converter unit 31 shown in FIG. 5 is purely an example with respect to the number and type of the respective components. Specifically, the converter unit 31 can have, for example, no, one, or more DC/AC converters 34, no, one, or more DC/DC converters 35, no, one or more transformers 36, and no, one or more switching systems 37.

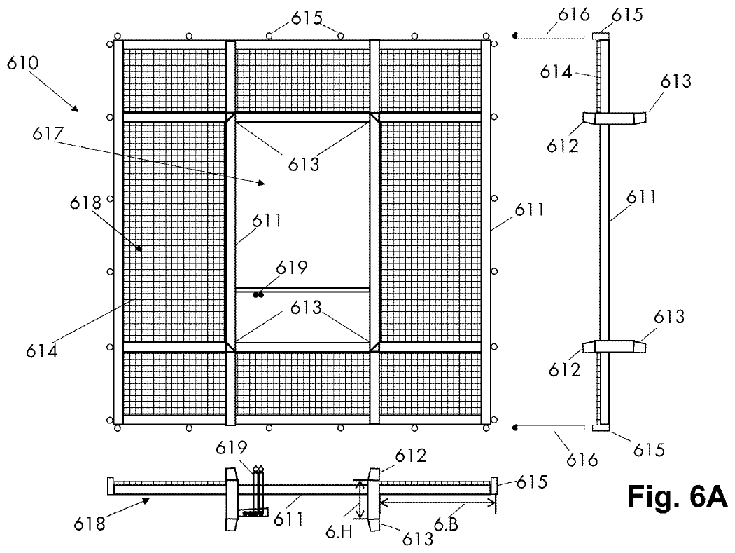

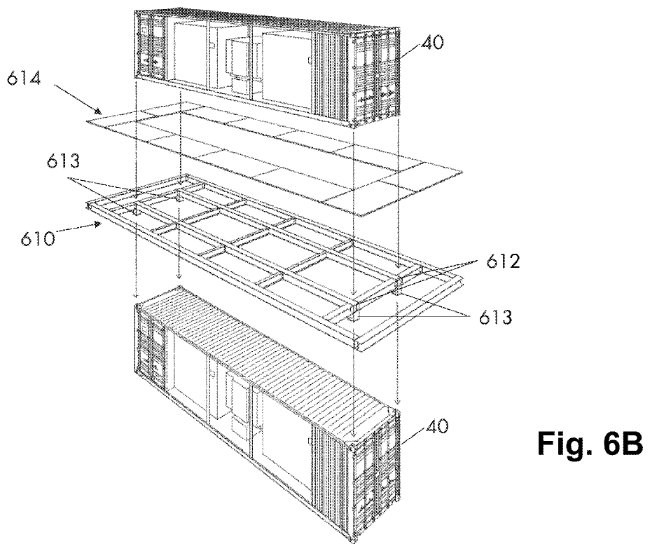

FIG. 6A shows an embodiment of a container platform 610 having a frame structure made of a plurality of beams 611 fixedly connected to one another. The container platform 610 is shown in a plan view and two side views, below the plan view and to the right thereof. The container platform 610 has an inner region 617, at the corner points of which upper alignment elements 612 are arranged as receiving points for a first container on an upper side of the frame structure. The upper alignment elements 612 are configured such that the first container 40 can be mounted on the upper alignment elements 612 in a defined position. The upper alignment elements 612 can enable an accommodation of standardized container corners with alignment and locking, and can be configured, for example, as twist-lock fasteners TL. Lower alignment elements 613, by means of which the container platform 610 can be placed onto a second container 40, are arranged on an underside of the container platform 610. The lower alignment elements 613 can be configured, for example, as standardized container corners—as are used in cargo containers, and known as so-called corner castings. The upper alignment elements 612 and the lower alignment elements 613 are spaced apart from one another in a direction perpendicular to the standing surface by a height 6.H so that the container platform 610 defines a distance corresponding to the height 6.H between the two containers 40. In an outer region 618 of the container platform 610 surrounding the inner region 617, floor panels 614 are placed on the frame structure, so that the outer region 618 is configured to be walkable in a width 6.B, and forms a standing surface on which loads can also be placed. In one embodiment, the floor panels 614 may comprise air-permeable gratings. In FIG. 6A, the standing surface completely surrounds the inner region 617 of the platform 610. Alternatively, however, it is also possible for the frame structure to have a standing surface in the form of a walkable or loadable outer region 618 only on one, two or three sides of the inner region 617.

Furthermore, the container platform 610 has guide elements, for example, cable channels, by means of which supply lines to the containers are guided. In the inner region 617, retaining elements 619 are arranged, for example, on a transverse strut of the frame structure in order to fix the supply lines at a specified position of the container platform 610, at which position a connection region of a container 40 placed on the upper side of the frame structure is located on the receiving points 612. In this way, a simple connection of the container 40 via the supply lines can be achieved. The connection can be an electrical connection, for example, an AC voltage grid or a DC voltage bus. In this case, the supply lines are configured as electrical supply lines. However, it is also conceivable for one or more of the supply lines not to be configured as electrical supply lines, but rather as supply lines transporting media, which can, for example, supply or discharge cooling liquid or gases.

Also mounted along the outer beams 611 are fastening elements for a railing 616 in the form of sleeves 615, into which the uprights of the railing 616 can be inserted. The fastening elements can be arranged circumferentially on all sides of the container platform 610, only on some sides, or on no side.

In an energy conversion installation 50, containers 40 can be stacked on top of one another as housings of components of the energy conversion installation 50, e.g., converter units 31, under the intermediate arrangement of the container platform 610.

The arrangement of containers 40 stacked one above the other, and a container platform 610, is shown in FIG. 6B in a perspective view in a further degree of detail. The frame structure of the container platform 610 is placed with its lower alignment elements 613 on the receiving points of the lower container 40. The upper container 40 is then placed on the upper alignment elements 612 of the container platform 610 in a position aligned to the lower container 40. By inserting floor panels 614 into the frame structure of the container platform 610, a walkable standing surface is formed which extends completely around the container platform 610 and thus allows access to the upper container 40 on all sides. The upper and lower alignment elements 612, 613 are arranged in such a way that they lead to a laterally centered arrangement of the upper container 40 above the lower container which arrangement is spaced apart vertically about a height of the container platform 610. Thus, multiple containers 40 can also be stacked one above the other within the stack 24 without the stack 24 being at risk of imbalance and falling.

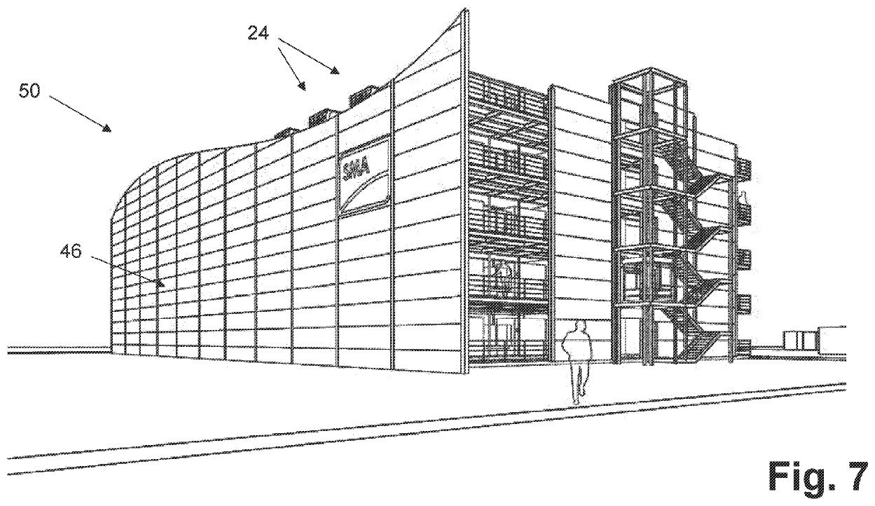

Multiple of the stacks 24 shown in the preceding figures can be formed as a building structure by attaching a facade 46 to the outer side of the plurality of stacks 24. In addition to a visual screen, the facade 46 can also contribute to the mechanical stability of the arrangement. Such a building structure is shown by way of example in FIG. 7. A staircase or an elevator can also be integrated into the building structure on the outside. In a further embodiment, stacks 24 can also be arranged on the outside of a building. The containers 40 and/or converter units 31 of one or more stacks 24 can form a functional unit, for example, an inverter and all energy storage devices connected on the DC voltage side of this inverter. In this way, the energy conversion installation 50 can be easily expanded by adding further stacks 24.

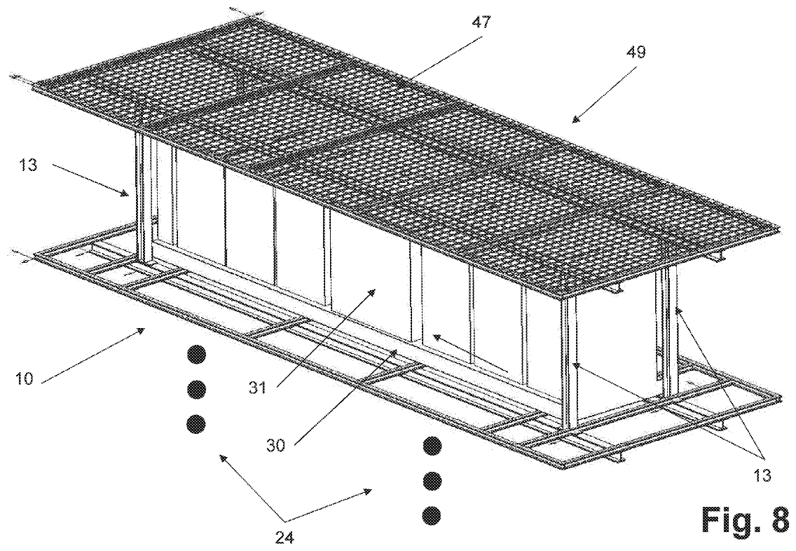

FIG. 8 illustrates an embodiment of a platform 10 which can be used as an upper platform 10 in a stack 24 of the energy conversion installation 50 (in FIG. 8, the stack 24 is merely symbolized in the form of points below the platform 10). The platform 10 has a metallic cover 49 for shielding electromagnetic interference radiation and/or for lightning protection. The metallic cover 49 includes a metal grating 47 and covers the skid 30 at its top, with the converter unit 31 arranged thereunder. The metallic cover 49 can be connected either directly (e.g., via separate cables) or indirectly (e.g., via an electrical contact to a grounded platform 10 located further below) to ground (not explicitly shown in FIG. 8).

In the case illustrated in FIG. 8, the support posts 13 and the converter unit 31—similarly to those in FIGS. 2A and 2B—are arranged on the same side of the frame structure. The metallic cover 49 containing the metal grating 47 can be mounted here on the support posts 13 of the upper platform 10, and therefore can be configured to be without support posts assigned thereto. Alternatively, however, it is also possible for the support posts 13 and the converter unit 31 of the platform 10 to be arranged on opposite sides of the frame structure. If all platforms 10 within the same stack have a similar arrangement of their support posts 13 and the converter units 31 arranged on them, stacking of the platforms 10 is also possible in a corresponding manner, as shown in FIGS. 2A and 2B. In order in this case to cover the converter unit 31 within the stack 24 at the top, the cover 49 can also have support posts with which it is fastened to the frame structure of the platform 10 in such a way that it covers the skid 30 at the top, with the converter unit 31.

What is claimed is:

1. A platform stack for a space-saving configuration of an energy conversion installation, comprising a first platform and a second platform stacked one over another in the platform stack, wherein:
the first platform is configured to position thereon a first skid with a first converter unit of the energy conversion installation, and wherein the second platform is configured to position thereon a second skid with a second converter unit of the energy conversion installation, wherein the first and the second platform are configured to stack together one over another to form the platform stack,
wherein the first platform comprises a frame structure having a support surface for the first skid, and wherein the first platform is at least largely without a wall surrounding the support surface around its periphery, comprises alignment elements on a first side of the frame structure, and comprises support posts on a second side of the frame structure opposite the first side,
wherein the frame structure also forms a standing surface which surrounds the support surface at least partially around its periphery, and which is configured to be walkable for persons for access to an item on the frame structure, and
wherein the support posts of the first platform are configured so that ends thereof work together in a stacked state with alignment elements of the second platform, to form a laterally centered and vertically spaced arrangement of the support surface of the first platform and the support surface of the second platform within the platform stack, and/or the alignment elements of the first platform are configured so that they work together in a stacked state with ends of the support posts of the second platform to form a laterally centered and vertically spaced arrangement of the support surface of the first platform and the support surface of the second platform within the platform stack, and
wherein, in the stacked state, a free space is formed between the support surfaces of the first platform and the second platform, for accommodating the first converter unit arranged on the first skid or the second converter unit arranged on the second skid, wherein the free space is without a wall surrounding the free space along at least a portion of a periphery thereof.

2. The platform stack according to claim 1, wherein the support surface for the first skid comprises a fire retardant material comprising a sandwich structure of two metal sheets and an intermediate non-combustible insulating material.

3. The platform stack according to claim 1, further comprising one or more sprinkler heads for fighting fires attached to the frame structure of at least one of the first platform and the second platform, wherein the one or more sprinkler heads are oriented to spray a component of the converter unit arranged on the respective one of the first platform and/or the second platform with the sprinkler heads and/or arranged underneath the respective one of the first platform and/or the second platform in the platform stack with the sprinkler heads.

4. The platform stack according to claim 1, wherein the alignment elements of the first platform are configured to surround upper corners of a container when the first platform is stacked on the container, thereby enabling lateral centering and fixing of the first platform on the container.

5. The platform stack according to claim 1, wherein the standing surface of at least one of the first platform and the second platform comprises floor panels comprising gratings.

6. The platform stack according to claim 1, wherein at least one of the first platform and the second platform comprises retaining elements configured to hold supply lines to the respective skid and/or the respective converter unit arranged thereon in a region of the support surface.

7. The platform stack according to claim 1, further comprising fastening elements for a railing laterally delimiting the standing surface, wherein the fastening elements are on at least one of the first platform and the second platform.

8. The platform stack according to claim 1, wherein a height of at least one of the first platform and the second platform is between 350 cm and 400 cm.

9. The platform stack according to claim 1, wherein a width of the standing surface of at least one of the first platform and the second platform is at least 1 m.

10. The platform stack according to claim 1, wherein the alignment elements or the ends of the support posts each comprise a twist-lock fastener.

11. An energy conversion installation for exchanging electrical power with a grid, comprising:
a platform stack comprising a first platform and a second platform stacked one over the other to form the platform stack:
wherein a first skid and a first converter unit of the energy conversion installation is positioned on the first platform, and/or wherein a second skid and a second converter unit of the energy conversion installation is positioned on the second platform, wherein the first platform and the second platform are stacked one over another to form the platform stack,
wherein each of the first platform and the second platform further comprises a frame structure having a support surface for its associated skid, and wherein each platform is at least largely without a wall surrounding the respective support surface around its periphery, and wherein each of the first and second platform comprises alignment elements on a first side of its respective frame structure, and comprises support posts on a second side of its respective frame structure opposite the first side,
wherein the frame structure of at least one of the first and the second platform also forms a standing surface which surrounds the support surface at least partially around its periphery, and which is configured to be walkable for persons as access to the respective converter unit, and
wherein the support posts of the first platform are configured so that ends thereof work together in a stacked state with alignment elements of the second platform, to form a laterally centered and vertically spaced arrangement of the support surface of the first platform and the support surface of the second platform within the stack, and/or the alignment elements of the first platform are configured so that they work together in a stacked state with support posts of the second platform to form a laterally centered and vertically spaced arrangement of the support surface of the first platform and the support surface of the second platform within the platform stack, and
wherein, in the stacked state, a free space is formed between the support surfaces of the first platform and the second platform, for accommodating the first converter unit arranged on the first skid or the second converter unit arranged on the second skid, wherein the free space is without a wall surrounding the free space along at least a portion of a periphery thereof.

12. The energy conversion installation according to claim 11, further comprising a sprinkler system having multiple sprinkler heads and supply lines connected thereto for supplying liquid, wherein the supply lines and/or the sprinkler heads comprise an electric heater.

13. The energy conversion installation according to claim 11, wherein the first and second converter units arranged on the first and second skids, respectively, each comprise one or more DC/AC converters, one or more DC/DC converters, one or more transformers and/or one or more switch assemblies.

14. The energy conversion installation according to claim 11, wherein the platform stack additionally comprises at least one container as a housing for components of the energy conversion installation, and wherein the platform stack with the first platform and the second platform is stacked on the at least one container.

15. The energy conversion installation according to claim 11, wherein the energy conversion installation is configured to provide reactive power for voltage stabilization in the grid and/or to provide power for frequency stabilization of the grid.

16. The energy conversion installation according to claim 11, wherein the energy conversion installation is configured as an uninterruptible power supply system which has decoupling elements to the grid and an energy storage device.

17. The energy conversion installation according to claim 11, additionally comprising at least one electrolyzer arranged in a container or on one of the first and second platforms.

18. The energy conversion installation according to claim 11, wherein the platform stack comprises two containers stacked on top of one another, with an interposition of a container platform therebetween, and wherein the platform stack with its two platforms is arranged on an upper one of the two containers.

19. The energy conversion installation according to claim 11, further comprising a plurality of platform stacks arranged side by side, such that adjacent ones of the platform stacks adjoin each other and a common plane of standing surfaces is formed.

20. The energy conversion installation according to claim 19, wherein the adjacent platform stacks extend in two different lateral directions.

21. The energy conversion installation according to claim 19, wherein the platform stacks are enclosed by a facade to form a building structure.

22. The energy conversion installation according to claim 21, wherein a height and/or a material of the facade comprises a noise absorbent material such that nuisance noise for adjacent residential buildings above a predetermined allowed noise level is prevented.

23. The energy conversion installation according to claim 11, wherein at least one of the first converter unit and the second converter unit is protected by sprayed and/or sprinkler water.

24. The energy conversion installation according to claim 11, wherein an upper of the platforms of one or more platform stacks comprises a metallic cover for the respective converter unit arranged thereon, wherein the metallic cover is configured to shield electromagnetic interference radiation and/or for providing lightning protection, wherein the metallic cover comprises a metal grating.
